(19) United States
(12) Patent Application Publication
(10) Pub. No.: US 2026/0282211 A1
(43) Pub. Date: Sep. 17, 2026

(54) CIRCUIT BOARD AND MANUFACTURING METHOD THEREOF

(71) Applicant: UNIMICRON TECHNOLOGY CORP., Taoyuan City (TW)

(72) Inventors: Kai-Yi YU, Taoyuan City (TW); Pu-Ju LIN, Taoyuan City (TW); Wei-Tse HO, Taoyuan City (TW); Cheng-Ta KO, Taoyuan City (TW)

(73) Assignee: UNIMICRON TECHNOLOGY CORP., Taoyuan City (TW)

(21) Appl. No.: 19/169,618

(22) Filed: Apr. 3, 2025

(30) Foreign Application Priority Data
Mar. 17, 2025 (TW) 114109876

(51) Int. Cl. H05K 1/02; H05K 1/03; H05K 1/11

(52) U.S. Cl. CPC H05K 1/0271; H05K 1/115; H05K 1/0306; H05K 2201/09509

(57) ABSTRACT

A circuit board and a manufacturing method thereof. The circuit board includes a glass substrate, a first build-up structure and at least one crack blocking structure. The glass substrate has a bottom surface, a top surface and a first side surface. The bottom surface and the top surface face away from each other. The first side surface connects the bottom surface and the top surface. The first build-up structure is disposed on the bottom surface or the top surface. The at least one crack blocking structure is disposed in the glass substrate and located adjacent to the first side surface.

### CROSS-REFERENCE TO RELATED APPLICATIONS

This non-provisional application claims priority under 35 U.S.C. § 119(a) on Patent Application No(s). 114109876 filed in Taiwan, R.O.C. on Mar. 17, 2025, the entire contents of which are hereby incorporated by reference.

### TECHNICAL FIELD

The disclosure relates to a circuit board and a manufacturing method thereof, more particularly to a circuit board including glass substrate and a manufacturing method of such circuit board.

### BACKGROUND

In general, a chipping damage may be caused when a glass substrate of a circuit board is cut. Moreover, the glass substrate and the build-up layer disposed thereon usually have different coefficients of thermal expansion, which generates stress and thus causes cracks around the area where the chipping damage occurs.

However, in a conventional circuit board, there is no structure near the side surface (e.g., scribed surface) of the glass substrate. Thus, such cracks may cause structural damage in an inner area of the glass substrate where electrical structures, such as circuits or wirings, are disposed by extending inwards from the side surface, which reduces the quality of the circuit board.

### SUMMARY

The disclosure provides a circuit board and a manufacturing method thereof to prevent cracks from extending inwards from the first side surface.

One embodiment of this disclosure provides a circuit board including a glass substrate, a first build-up structure and at least one crack blocking structure. The glass substrate has a bottom surface, a top surface and a first side surface. The bottom surface and the top surface face away from each other. The first side surface connects the bottom surface and the top surface. The first build-up structure is disposed on the bottom surface or the top surface. The at least one crack blocking structure is disposed in the glass substrate and located adjacent to the first side surface.

In an embodiment of the disclosure, the at least one crack blocking structure extends along a stacking direction of the glass substrate and the first build-up structure.

In an embodiment of the disclosure, the at least one crack blocking structure includes at least one blind via structure located adjacent to the first side surface and disposed on the bottom surface or the top surface.

In an embodiment of the disclosure, the at least one blind via structure of the at least one crack blocking structure includes two blind via structures. The two blind via structures are located adjacent to the first side surface and disposed on the bottom surface and the top surface, respectively.

In an embodiment of the disclosure, the two blind via structures of the at least one crack blocking structure are overlapped with and spaced apart from each other along the stacking direction.

In an embodiment of the disclosure, the at least one crack blocking structure includes a through via structure located adjacent to the first side surface and disposed on the bottom surface and the top surface.

In an embodiment of the disclosure, the circuit board further includes a second build-up structure and at least one conductive through via. The first build-up structure includes a first dielectric layer and a first circuit layer disposed in the first dielectric layer. The second build-up structure includes a second dielectric layer and a second circuit layer disposed in the second dielectric layer. The first dielectric layer and the second dielectric layer are disposed on the bottom surface and the top surface, respectively. The at least one conductive through via is disposed in the glass substrate and electrically connects the first circuit layer and the second circuit layer.

In an embodiment of the disclosure, the at least one crack blocking structure includes a plurality of crack blocking structures. The at least one conductive through via includes a plurality of conductive through vias. A gap between the plurality of crack blocking structures located adjacent to each other is 3.5 times larger than a gap between the plurality of conductive through vias located adjacent to each other.

In an embodiment of the disclosure, the plurality of crack blocking structures surrounds the plurality of conductive through vias.

In an embodiment of the disclosure, in the stacking direction, the at least one crack blocking structure is not overlapped with the first circuit layer and the second circuit layer.

In an embodiment of the disclosure, the at least one crack blocking structure is electrically insulated from the first circuit layer and the second circuit layer.

In an embodiment of the disclosure, a distance between the at least one crack blocking structure and the first side surface is larger than or equal to 100 micrometers and smaller than or equal to 350 micrometers.

Another embodiment of this disclosure provides a manufacturing method of circuit board including: providing a glass substrate; disposing at least one crack blocking structure in the glass substrate; disposing a first build-up structure on a bottom surface or a top surface of the glass substrate; and cutting the glass substrate and the first build-up structure along a scribe line to form at least one circuit board including the at least one crack blocking structure located adjacent to a first side surface of the glass substrate.

In an embodiment of the disclosure, a ratio of a distance between the crack blocking structure and the first side surface to a width of the scribe line is larger than or equal to 1/7 and smaller than or equal to 1.75.

In an embodiment of the disclosure, the width of the scribe line is larger than or equal to 200 micrometers and smaller than or equal to 700 micrometers.

According to the circuit board and the manufacturing method thereof, since the crack blocking structure adjacent to the first side surface is disposed in the glass substrate, even though a stress is generated due to the difference between the coefficient of thermal expansion of the glass substrate and that of the first build-up structure, such stress merely causes crack between the crack blocking structure and the first side surface. That is, the crack blocking structure prevents the crack caused by the said stress from extend inwards. In this way, the structural damage in an inner area of the glass substrate where electrical structures, such as circuits or wirings, are disposed is prevented, which prevents the quality of the semi-finished circuit board from being reduced.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIGS. 1 to 6 are cross-sectional views showing a manufacturing method of a circuit board according to a first embodiment of the disclosure;

FIG. 7 is a perspective view of the circuit board according to the first embodiment of the disclosure;

FIG. 8 is a schematic top view of the circuit board in FIG. 7; and

FIG. 9 is a cross-sectional view of a circuit board according to a second embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

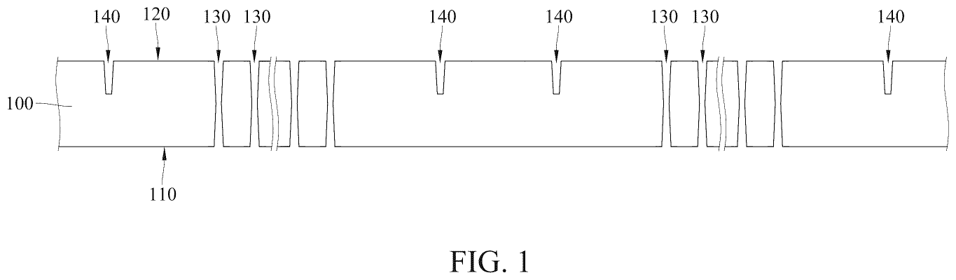

Please refer to FIGS. 1 to 6 that are cross-sectional views showing a manufacturing method of a circuit board 10 according to a first embodiment of the disclosure. In this embodiment, the manufacturing method of the circuit board 10 may include following steps.

As shown in FIG. 1, a glass substrate 100 is provided. The glass substrate 100 has a bottom surface 110 and a top surface 120 facing away from each other. In addition, the glass substrate 100 further has, for example, a plurality of through holes 130 and a plurality of blind holes 140. The through holes 130 penetrate through the bottom surface 110 and the top surface 120. The blind holes 140 are located on the top surface 120.

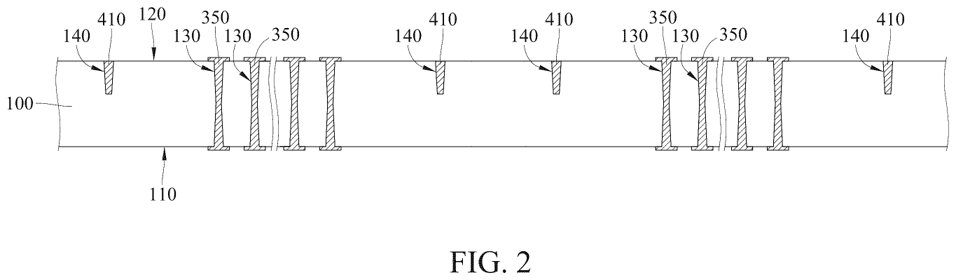

Then, as shown in FIG. 2, a plurality of conductive through vias 350 is formed in the through holes 130, respectively, and a plurality of blind via structures 410 is formed in the blind holes 140, respectively.

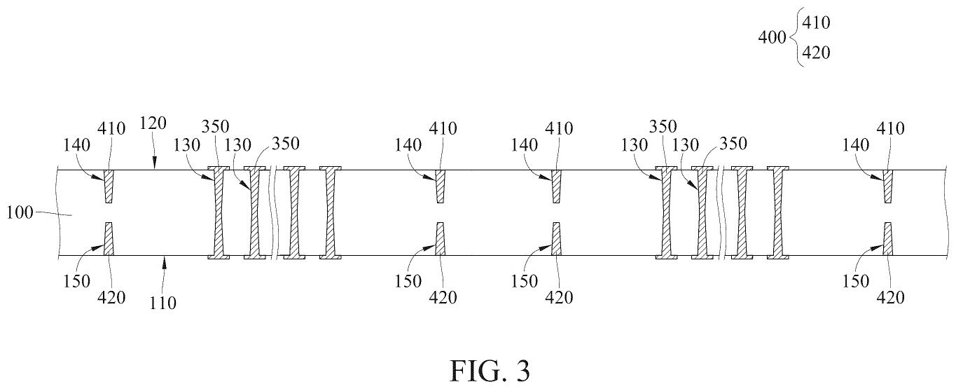

Then, as shown in FIG. 3, a plurality of blind holes 150 is formed on the bottom surface 110, and a plurality of blind via structures 420 is formed in the blind holes 150, respectively. One blind via structure 410 and one blind via structure 420 located adjacent to each other together configure, for example, one crack blocking structure 400; additionally, the blind via structures may be formed on the top surface and the bottom surface simultaneously in one step.

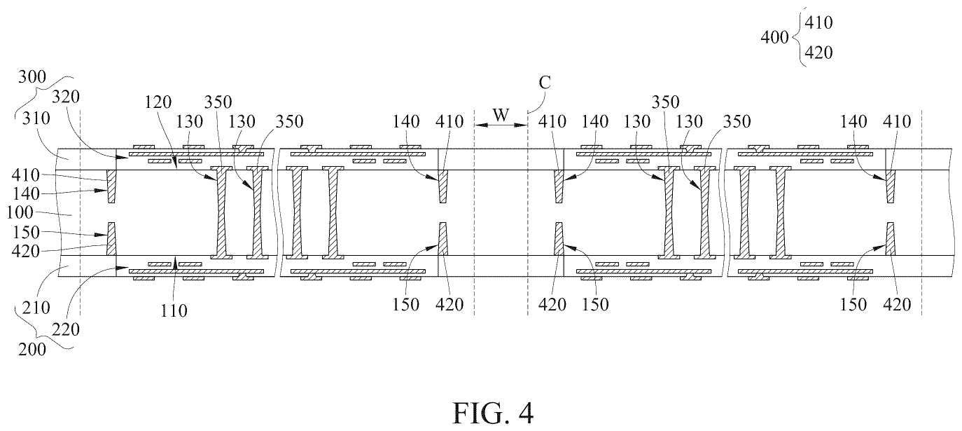

Then, as shown in FIG. 4, a first build-up structure 200 and a second build-up structure 300 are formed on the bottom surface 110 and the top surface 120, respectively. In this embodiment, the first build-up structure 200 includes a first dielectric layer 210 and a first circuit layer 220 disposed in the first dielectric layer 210. The second build-up structure 300 includes a second dielectric layer 310 and a second circuit layer 320 disposed in the second dielectric layer 310. The first dielectric layer 210 and the second dielectric layer 310 are disposed on the bottom surface 110 and the top surface 120, respectively. The conductive through vias 350 electrically connect the first circuit layer 220 and the second circuit layer 320.

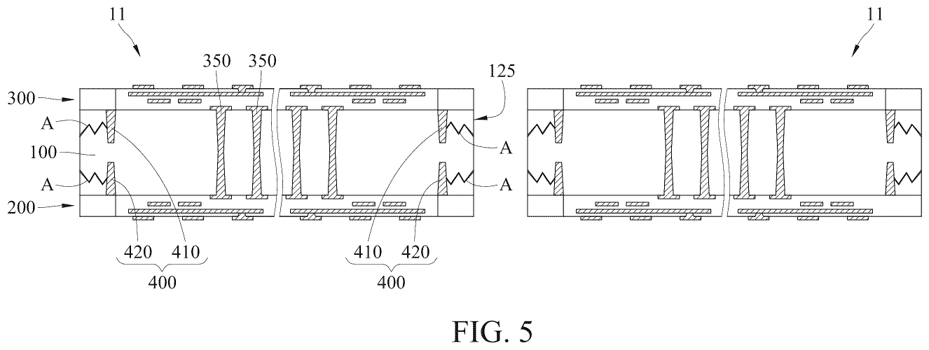

Then, as shown in FIGS. 4 and 5, the glass substrate 100, the first build-up structure 200 and the second build-up structure 300 are cut along a scribe line C to form, for example, two semi-finished circuit boards 11. A width W of the scribe line C is, for example, larger than or equal to 200 micrometers (um) and smaller than or equal to 700 um. After the cutting process, the glass substrate 100 has a first side surface 125. The first side surface 125 is, for example, a side scribed surface, and connects the bottom surface 110 and the top surface 120. As shown in FIG. 5, since the crack blocking structure 400 located adjacent to the first side surface 125 is disposed in the glass substrate 100, even though a stress is generated due to the difference between the coefficient of thermal expansion of the glass substrate 100 and those of the first build-up structure 200 and the second build-up structure 300 (e.g., the first circuit layer 220 and the second circuit layer 320), such stress merely causes crack A between the crack blocking structure 400 and the first side surface 125. That is, the crack blocking structure 400 prevents the crack A caused by the said stress from extend inwards. In this way, the structural damage in an inner area of the glass substrate 100 where electrical structures, such as circuits or wirings, are disposed is prevented, which prevents the quality of the semi-finished circuit board 11 from being reduced. Furthermore, the crack blocking structure 400 of this embodiment includes the blind via structures 410 and 420. Thus, the crack blocking structure 400 is allowed to have lower manufacture cost while being able to block the cracks from extending inwards.

Note that in this embodiment, two semi-finished circuit boards 11 are formed after cutting process to save the material for manufacture, but the disclosure is not limited thereto. In other embodiments, the glass substrate, the first build-up structure and the second build-up structure may each be partially cut to form one semi-finished circuit board 11 after the cutting process.

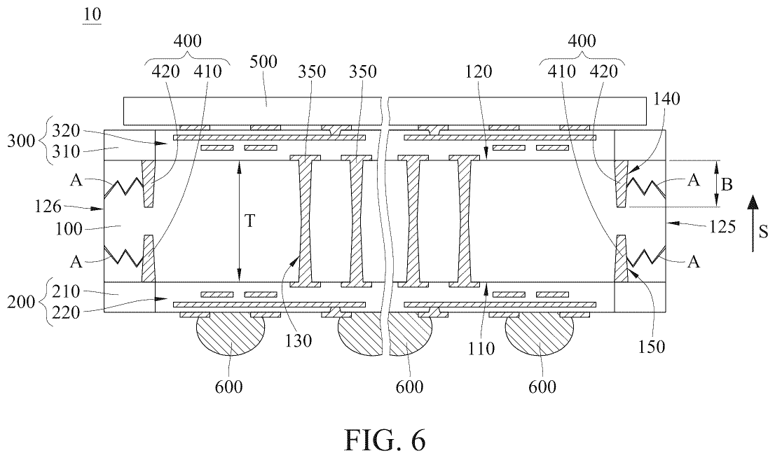

Then, as shown in FIG. 6, a chip 500 is electrically connected to the second circuit layer 320, and a plurality of solder balls 600 is electrically connected to the first circuit layer 220. So far, the manufacture of the circuit board 10 is completed. That is, the only difference between the semi-finished circuit board 11 in FIG. 5 and the circuit board 10 is that the circuit board 10 further includes the chip 500 and the solder balls 600.

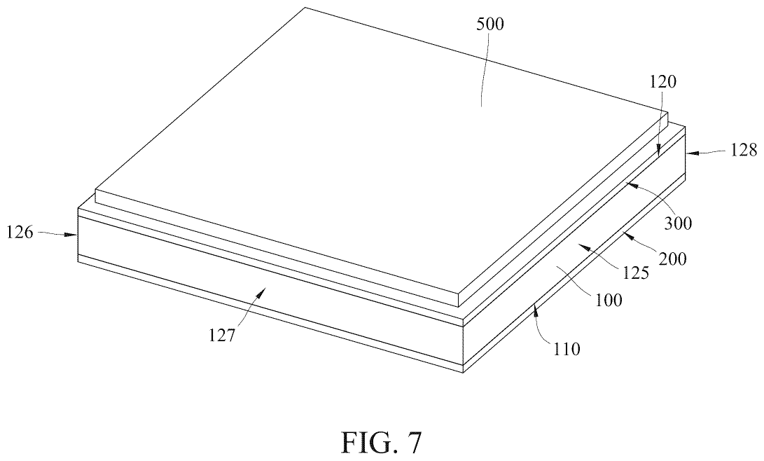

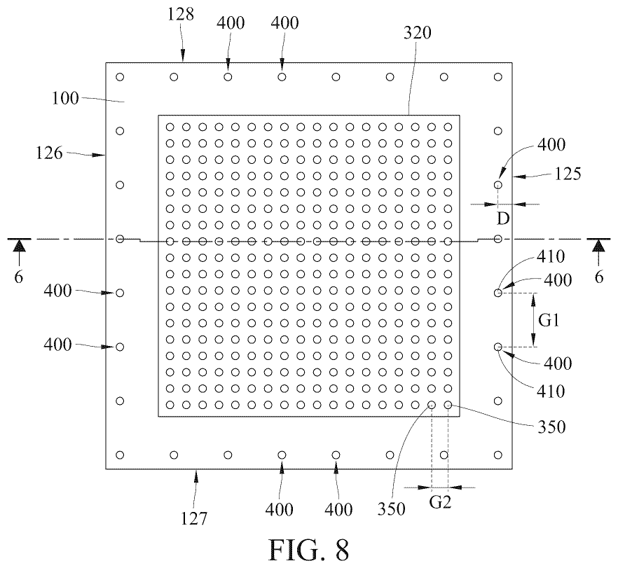

Hereinafter, the detailed structure of the circuit board 10 will be described by referring to FIGS. 6 to 8. FIG. 7 is a perspective view of the circuit board 10 according to the first embodiment of the disclosure. FIG. 8 is a schematic top view of the circuit board 10 in FIG. 7. Note that FIG. 6 is a partially enlarged cross-sectional view of the circuit board 10 taken along line 6-6 in FIG. 8.

In this embodiment, the circuit board 10 includes, for example, the glass substrate 100, the first build-up structure 200, the second build-up structure 300, the conductive through vias 350, the crack blocking structures 400, the chip 500 and the solder balls 600. A thickness of the glass substrate 100 is, for example, 1.1 millimeter (mm). The first build-up structure 200 and the second build-up structure 300 are disposed on the bottom surface 110 and the top surface 120 of the glass substrate 100, respectively. The conductive through vias 350 electrically connect the first circuit layer 220 of the first build-up structure 200 and the second circuit layer 320 of the second build-up structure 300. The chip 500 is electrically connected to the second circuit layer 320. The solder balls 600 are electrically connected to the first circuit layer 220. In other embodiments, the circuit board may not include the first build-up structure 200 or the second build-up structure 300 according to actual requirements. In such embodiments, the circuit board may not include the conductive through vias.

In this embodiment, the blind via structures 410 and 420 of the crack blocking structures 400 extend along, for example, a stacking direction S of the glass substrate 100, the first build-up structure 200 and the second build-up structure 300. In other words, the crack blocking structures 400 extend vertically. A depth B of each blind via structure 410 and 420 is, for example, larger than or equal to 50 um and smaller than or equal to 200 um.

Further, in this embodiment, each crack blocking structure 400 includes two blind via structures 410 and 420 that are disposed on the top surface 120 and the bottom surface 110, respectively. However, the disclosure is not limited thereto. In other embodiments, each crack blocking structure may merely include one blind via structure disposed on the top surface or the bottom surface, and the depth of this blind via structure may be adjusted according to the thickness of the glass substrate in the range from 50 um to 200 um.

In addition, the blind via structures 410 and 420 in each crack blocking structure 400 are overlapped with and spaced apart from each other along the stacking direction S, so as to facilitate the manufacture of the blind via structures 410 and 420. In other embodiments, the two blind via structures of each crack blocking structure may be misaligned with and spaced apart from each other without considering the convenience of the manufacture.

Moreover, in this embodiment, the crack blocking structures 400 are electrically insulated from the first circuit layer 220 and the second circuit layer 320. That is, unlike the conductive through vias 350, the crack blocking structures 400 are not act as the media through which the first circuit layer 220 and the second circuit layer 320 are electrically connected. If the crack blocking structures 400 also act as the media through which the first circuit layer 220 and the second circuit layer 320 are electrically connected, the resistance between the first circuit layer 220 and the second circuit layer 320 will be increased. That is, the electrical insulation between the crack blocking structures 400 and the first circuit layer 220 and the second circuit layer 320 prevents the resistance between the first circuit layer 220 and the second circuit layer 320 from being increased by the crack blocking structures 400, which ensures the first circuit layer 220 and the second circuit layer 320 to have excellent electrical property. Furthermore, as shown in FIGS. 6 and 8, in the stacking direction S, the crack blocking structures 400, for example, are not overlapped with the first circuit layer 220 and the second circuit layer 320.

Also, in this embodiment, the crack blocking structures 400 are made of, for example, copper to facilitate the manufacture of the crack blocking structures 400, but the disclosure is not limited thereto. In other embodiments, the crack blocking structures may be made of a metal material other than copper or a non-metal material.

Note that in FIG. 8, in order to clearly show the position relationship between the glass substrate 100, the second circuit layer 320, the conductive through vias 350 and the crack blocking structures 400, the chip 500 is omitted and the conductive through vias 350 and the crack blocking structures 400 that practically are not exposed to the outside are denoted by solid lines.

Please refer to FIG. 8, in this embodiment, the crack blocking structures 400 surround the conductive through vias 350. Specifically, the crack blocking structures 400 are located adjacent to the first side surface 125, a second side surface 126, a third side surface 127 and a fourth side surface 128 of the glass substrate 100, respectively. The first side surface 125, the second side surface 126, the third side surface 127 and the fourth side surface 128 connect the bottom surface 110 and the top surface 120. The first side surface 125 and the second side surface 126 face away from each other. The third side surface 127 and the fourth side surface 128 face away from each other, and are located between the first side surface 125 and the second side surface 126. All of the first side surface 125, the second side surface 126, the third side surface 127 and the fourth side surface 128 may be side scribed surfaces. Note that in other embodiments, there may be one crack blocking structure that does not surround the conductive through vias.

Moreover, a gap G1 between adjacent crack blocking structures 400 is, for example, 3.5 times larger than a gap G2 between adjacent conductive through vias 350. Further, a distance D between the crack blocking structures 400 and the first side surface 125 is, for example, larger than or equal to 100 um and smaller than or equal to 350 um. In other words, a ratio of the distance D between the crack blocking structures 400 and the first side surface 125 to the width W of the scribe line C in FIG. 4 is, for example, larger than or equal to 1/7 and smaller than or equal to 1.75.

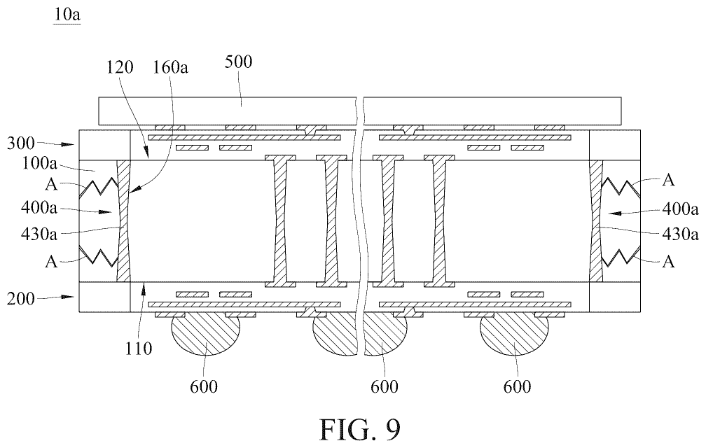

Note that the disclosure is not limited by the structure of the crack blocking structures. Please refer to FIG. 9 that is a cross-sectional view of a circuit board 10a according to a second embodiment of the disclosure. The only difference between the circuit board 10a of this embodiment and the circuit board 10 of the first embodiment is the structure of the crack blocking structures. In detail, in this embodiment, each crack blocking structure 400a of the circuit board 10a includes a through via structure 430a. The through via structure 430a is disposed on the bottom surface 110 and the top surface 120. Correspondingly, a glass substrate 100a may have a plurality of through holes 160a. The through via structures 430a are disposed in the through holes 160a, respectively. The through holes 160a penetrate through the bottom surface 110 and the top surface 120. The through via structures 430a are able to further ensured that the crack is prevented from extending inwards.

According to the circuit board and the manufacturing method thereof, since the crack blocking structure adjacent to the first side surface is disposed in the glass substrate, even though a stress is generated due to the difference between the coefficient of thermal expansion of the glass substrate and that of the first build-up structure, such stress merely causes crack between the crack blocking structure and the first side surface. That is, the crack blocking structure prevents the crack caused by the said stress from extend inwards. In this way, the structural damage in an inner area of the glass substrate where electrical structures, such as circuits or wirings, are disposed is prevented, which prevents the quality of the semi-finished circuit board from being reduced.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A circuit board, comprising:
a glass substrate, having a bottom surface, a top surface and a first side surface, wherein the bottom surface and the top surface face away from each other, and the first side surface connects the bottom surface and the top surface;
a first build-up structure, disposed on the bottom surface or the top surface; and
at least one crack blocking structure, disposed in the glass substrate and located adjacent to the first side surface.

2. The circuit board according to claim 1, wherein the at least one crack blocking structure extends along a stacking direction of the glass substrate and the first build-up structure.

3. The circuit board according to claim 2, wherein the at least one crack blocking structure comprises at least one blind via structure located adjacent to the first side surface and disposed on the bottom surface or the top surface.

4. The circuit board according to claim 3, wherein the at least one blind via structure of the at least one crack blocking structure comprises two blind via structures, and the two blind via structures are located adjacent to the first side surface and disposed on the bottom surface and the top surface, respectively.

5. The circuit board according to claim 4, wherein the two blind via structures the at least one crack blocking structure are overlapped with and spaced apart from each other along the stacking direction.

6. The circuit board according to claim 2, wherein the at least one crack blocking structure comprises a through via structure located adjacent to the first side surface and disposed on the bottom surface and the top surface.

7. The circuit board according to claim 2, further comprising a second build-up structure and at least one conductive through via, wherein the first build-up structure comprises a first dielectric layer and a first circuit layer disposed in the first dielectric layer, the second build-up structure comprises a second dielectric layer and a second circuit layer disposed in the second dielectric layer, the first dielectric layer and the second dielectric layer are disposed on the bottom surface and the top surface, respectively, and the at least one conductive through via is disposed in the glass substrate and electrically connects the first circuit layer and the second circuit layer.

8. The circuit board according to claim 7, wherein the at least one crack blocking structure comprises a plurality of crack blocking structures, the at least one conductive through via comprises a plurality of conductive through vias, a gap between the plurality of crack blocking structures located adjacent to each other is 3.5 times larger than a gap between the plurality of conductive through vias located adjacent to each other.

9. The circuit board according to claim 8, wherein the plurality of crack blocking structures surrounds the plurality of conductive through vias.

10. The circuit board according to claim 7, wherein in the stacking direction, the at least one crack blocking structure is not overlapped with the first circuit layer and the second circuit layer.

11. The circuit board according to claim 7, wherein the at least one crack blocking structure is electrically insulated from the first circuit layer and the second circuit layer.

12. The circuit board according to claim 1, wherein a distance between the at least one crack blocking structure and the first side surface is larger than or equal to 100 micrometers and smaller than or equal to 350 micrometers.

13. A manufacturing method of circuit board, comprising:
providing a glass substrate;
disposing at least one crack blocking structure in the glass substrate;
disposing a first build-up structure on a bottom surface or a top surface of the glass substrate; and
cutting the glass substrate and the first build-up structure along a scribe line to form at least one circuit board comprising the at least one crack blocking structure located adjacent to a first side surface of the glass substrate.

14. The manufacturing method of circuit board according to claim 13, wherein a ratio of a distance between the crack blocking structure and the first side surface to a width of the scribe line is larger than or equal to 1/7 and smaller than or equal to 1.75.

15. The manufacturing method of circuit board according to claim 13, wherein the width of the scribe line is larger than or equal to 200 micrometers and smaller than or equal to 700 micrometers.
